(19) United States
(12) Patent Application Publication
(10) Pub. No.: US 2025/0081757 A1
(43) Pub. Date: Mar. 6, 2025

(54) DISPLAY DEVICE AND METHOD OF MANUFACTURING THE SAME

(71) Applicant: Samsung Display Co., LTD., Yongin-si (KR)

(72) Inventors: WAN NAMGUNG, Yongin-si (KR); EON-YOUNG KIM, Yongin-si (KR); HEEJIN JEON, Yongin-si (KR); SUMIN CHOI, Yongin-si (KR)

(21) Appl. No.: 18/805,203

(22) Filed: Aug. 14, 2024

(30) Foreign Application Priority Data
Aug. 29, 2023 (KR) 10-2023-0113710

(51) Int. Cl. H10K 59/124; H10K 59/12; H10K 59/131

(52) U.S. Cl. CPC H10K 59/124; H10K 59/1201; H10K 59/131

(57) ABSTRACT

A display device includes: a substrate; an active pattern disposed on the substrate; an insulating layer disposed on the active pattern and defining an opening exposing a portion of the active pattern; a first conductive layer including a first conductive pattern, which is disposed on the insulating layer and contacts a side surface of the insulating layer defining the opening, and a second conductive pattern, which is disposed on the active pattern in the opening and is disconnected from the first conductive pattern; an organic layer pattern disposed in the opening, contacting the first conductive pattern and the second conductive pattern, and exposing a portion of the second conductive pattern; and a second conductive layer covering the organic layer pattern and a side surface of the first conductive pattern, and contacting the second conductive pattern.

This application claims priority to Korean Patent Application No. 10-2023-0113710, filed on Aug. 29, 2023, and all the benefits accruing therefrom under 35 U.S.C. § 119, the content of which in its entirety is herein incorporated by reference.

### BACKGROUND

### 1. Field

The present disclosure relates generally to a display device. More particularly, the present disclosure relates to a display device and a method of manufacturing the same.

### 2. DESCRIPTION OF THE RELATED ART

With the development of information technology, the importance of a display device, which is a connection medium between a user and information, has been highlighted. For example, the use of display devices such as liquid crystal display (“LCD”) device, organic light emitting display (“OLED”) device, plasma display panel (“PDP”) device, quantum dot display device or the like is increasing.

The display device may include a thin film transistor (“TFT”), a capacitor, etc. as a driving circuit. The thin film transistor may include an active pattern, a gate electrode electrically insulated from the active pattern, and a source electrode and a drain electrode electrically connected to the active pattern through an opening. Recently, the thin film transistor has been increasingly integrated to improve the resolution of the display device.

### SUMMARY

Embodiments provide a display device with improved contact between an active pattern and an electrode.

Embodiments provide a method of manufacturing the display device.

A display device according to an embodiment of the present disclosure includes: a substrate; an active pattern disposed on the substrate; an insulating layer disposed on the active pattern and defining an opening exposing a portion of the active pattern; a first conductive layer including a first conductive pattern, which is disposed on the insulating layer and contacts a side surface of the insulating layer defining the opening, and a second conductive pattern, which is disposed on the active pattern in the opening and is disconnected from the first conductive pattern; an organic layer pattern disposed in the opening, contacting the first conductive pattern and the second conductive pattern, and exposing a portion of the second conductive pattern; and a second conductive layer covering the organic layer pattern and a side surface of the first conductive pattern, and contacting the second conductive pattern.

In an embodiment, an edge of an upper surface of the first conductive pattern may protrude further than an edge of a lower surface of the first conductive pattern in a direction toward a center of the opening. The first conductive pattern and the second conductive pattern may define an undercut structure in the opening.

In an embodiment, the organic layer pattern may be disposed to fill a space defined by the undercut structure.

In an embodiment, the organic layer pattern may connect the first conductive pattern

and the second conductive pattern, which are disconnected from each other.

In an embodiment, the second conductive layer may extend continuously in the opening.

In an embodiment, the second conductive layer may cover an upper surface of the second conductive pattern exposed from the organic layer pattern.

In an embodiment, the organic layer pattern may include a positive photosensitive organic material.

In an embodiment, the organic layer pattern may include a non-photosensitive organic material.

In an embodiment, the active pattern may include a first active pattern disposed on the substrate and a second active pattern disposed on the first active pattern. The opening may include a first opening exposing a portion of the first active pattern and a second opening exposing a portion of the second active pattern. The organic layer pattern may be disposed in the first opening.

In an embodiment, the organic layer pattern may further be disposed in the second opening.

A method of manufacturing a display device according to an embodiment of the present disclosure includes: forming an active pattern on a substrate and forming an insulating layer on the active pattern; forming an opening exposing a portion of the active pattern in the insulating layer; forming a first conductive layer including a first conductive pattern, which is disposed on the insulating layer and contacts a side surface of the insulating layer defining the opening, and a second conductive pattern, which is disposed on the active pattern in the opening and is disconnected from the first conductive pattern; forming a preliminary organic layer on the first conductive layer; forming an organic layer pattern, which contacts the first conductive pattern and the second conductive pattern in the opening and exposes a portion of the second conductive pattern, by patterning the preliminary organic layer; and forming a second conductive layer which covers the organic layer pattern and a side surface of the first conductive pattern and contacts the second conductive pattern.

In an embodiment, an edge of an upper surface of the first conductive pattern may be formed to protrude further than an edge of a lower surface of the first conductive pattern in a direction toward a center of the opening. The first conductive pattern and the second conductive pattern may define an undercut structure in the opening.

In an embodiment, the organic layer pattern may be formed to fill a space defined by the undercut structure.

In an embodiment, the organic layer pattern may be formed by exposing the preliminary organic layer to a light using the first conductive pattern as a mask.

In an embodiment, the organic layer pattern may be formed by etching the preliminary organic layer using the first conductive pattern as a mask.

In an embodiment, each of the first conductive layer and the second conductive layer may be formed through a sputtering process.

In an embodiment, the second conductive layer may be formed to extend continuously in the opening.

In an embodiment, the second conductive layer may be formed to cover an upper surface of the second conductive pattern exposed from the organic layer pattern.

In an embodiment, the forming of the active pattern on the substrate may include forming a first active pattern on the substrate and forming a second active pattern on the first active pattern. The forming of the opening in the insulating layer may include forming a first opening exposing a portion of the first active pattern and forming a second opening exposing a portion of the second active pattern. The organic layer pattern may be formed in the first opening.

In an embodiment, the organic layer pattern may be further formed in the second opening.

A display device according to an embodiment of the present disclosure may include an insulating layer disposed on an active pattern and defining an opening exposing a portion of the active pattern, a first conductive layer including a first conductive pattern, which contacts a side surface of the insulating layer defining the opening, and a second conductive pattern, which is disposed on the active pattern in the opening and is disconnected from the first conductive pattern, an organic layer pattern disposed in the opening, contacting the first conductive pattern and the second conductive pattern, and exposing a portion of the second conductive pattern, and a second conductive layer contacting the second conductive pattern.

The organic layer pattern may fill a disconnected space between the first conductive pattern and the second conductive pattern in the opening. Accordingly, the second conductive layer may extend continuously in the opening without being disconnected. The second conductive layer may be electrically connected to the active pattern through the second conductive pattern. That is, even if a disconnection occurs in the first conductive layer, the second conductive layer may be electrically connected to the active pattern.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is a cross-sectional view taken along line I-I′ of FIG. 1.

FIG. 3 is an enlarged cross-sectional view of area ‘A’ of FIG. 2.

FIG. 4 is a plan view illustrating a display device according to another embodiment of the present disclosure.

FIG. 5 is a cross-sectional view taken along line II-II′ of FIG. 4.

FIG. 6 is an enlarged cross-sectional view of area ‘B’ of FIG. 5.

FIG. 7 is a flowchart of a method of manufacturing a display device according to an embodiment of the present disclosure.

FIGS. 8, 9, 10, 11, 12, 13, 14, 15, 16, and 17 are views illustrating the method of manufacturing the display device of FIG. 7.

### DETAILED DESCRIPTION OF THE EMBODIMENTS

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when an element is referred to as being “on” another element or “connected to” another element, it can be directly on or directly connected to the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Hereinafter, embodiments of the present disclosure will be described in detail with reference to the accompanying drawings. The same reference numerals are used for the same components in the drawings, and redundant descriptions of the same components will be omitted.

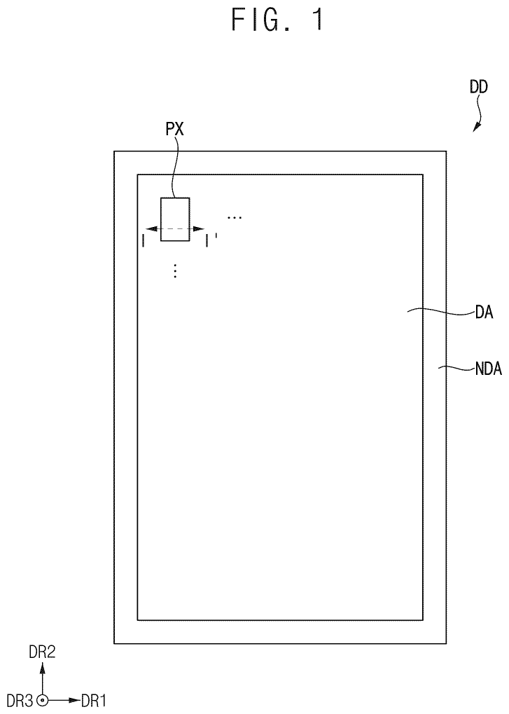

FIG. 1 is a plan view illustrating a display device according to an embodiment of the present disclosure. As used herein, the “plan view” is a view in a thickness direction (i.e., third direction DR3) of the substrate SUB.

In this specification, a plane may be defined by a first direction DR1 and a second direction DR2 crossing the first direction DR1. For example, the first direction DR1 and the second direction DR2 may be perpendicular to each other. A direction normal to the plane, that is, a thickness direction of a display device DD may be a third direction DR3. In other words, the third direction DR3 may be perpendicular to each of the first direction DR1 and the second direction DR2.

Referring to FIG. 1, the display device DD according to an embodiment of the present disclosure may include a display area DA and a non-display area NDA.

The display area DA may be defined as an area that displays an image by generating light or adjusting the transmittance of light provided from an external light source. A plurality of pixels PX may be disposed in the display area DA. The pixels PX may generate light according to a driving signal. The pixels PX may be repeatedly disposed along the first direction DR1 and the second direction DR2.

Data lines, gate lines, and light emitting control lines that are connected to the pixels PX may be further disposed in the display area DA. The data lines may provide a data voltage to the pixels PX. The gate line may provide a gate signal to the pixels PX. The light emitting control lines may provide a light emitting control signal to the pixels PX.

The non-display area NDA may be defined as an area that does not display an image. The non-display area NDA may be positioned around the display area DA. For example, the non-display area NDA may surround the entirety of the display area DA.

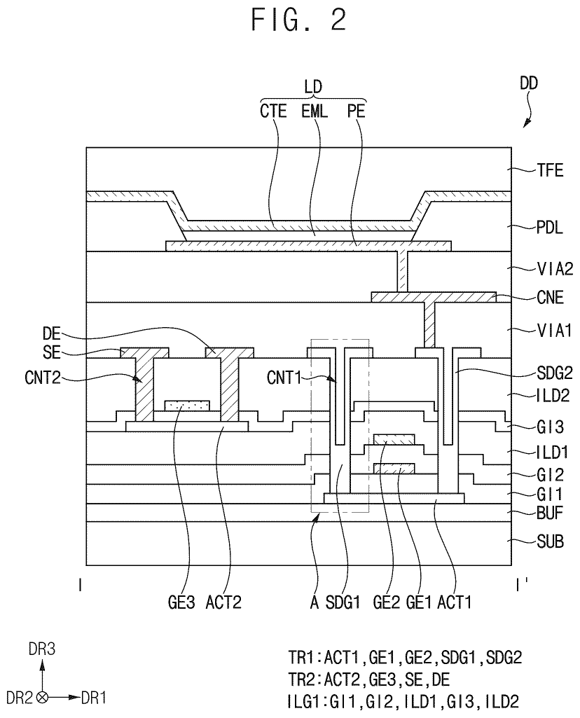

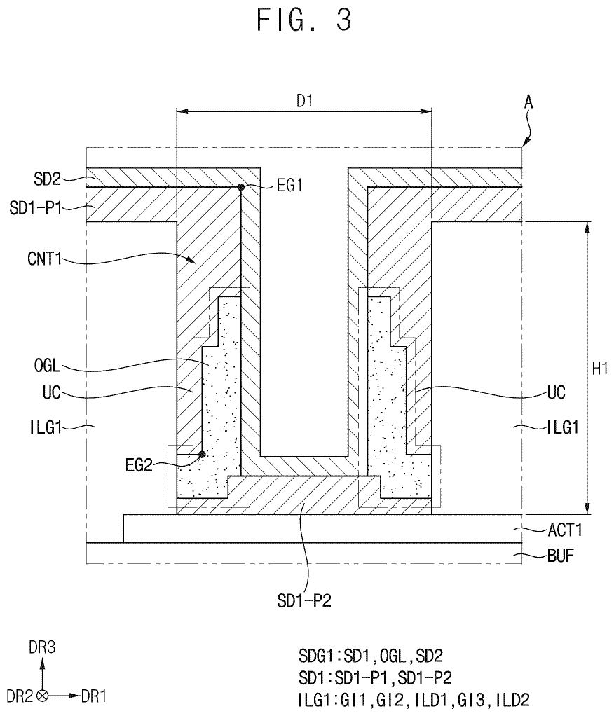

FIG. 2 is a cross-sectional view taken along line I-I′ of FIG. 1. FIG. 3 is an enlarged cross-sectional view of area ‘A’ of FIG. 2.

Referring to FIGS. 2 and 3, the display device DD according to an embodiment of the present disclosure may include a substrate SUB, a buffer layer BUF, a first transistor TR1, a second gate electrode GE2, a second transistor TR2, a first insulating layer group ILG1, a first via-insulating layer VIA1, a second via-insulating layer VIA2, a connection electrode CNE, a pixel defining layer PDL, a light emitting element LD, and an encapsulation layer TFE.

The first transistor TRI may include a first active pattern ACT1, a first gate electrode GE1, a first source-drain structure SDG1, and a second source-drain structure SDG2. The second transistor TR2 may include a second active pattern ACT2, a third gate electrode GE3, a source electrode SE, and a drain electrode DE. The first insulating layer group ILG1 may include a first gate insulating layer GI1, a second gate insulating layer GI2, a first inter-layer insulating layer ILD1, a third gate insulating layer GI3, and a second inter-layer insulating layer ILD2. The light emitting element (“LD”) may include a pixel electrode PE, a light emitting layer EML, and a common electrode CTE.

The substrate SUB may include a transparent material or an opaque material. The substrate SUB may be formed of or include a transparent resin substrate. A polyimide substrate may be an example of the transparent resin substrate. In this case, the polyimide substrate may include a first organic layer, a first barrier layer, a second organic layer, etc. Alternatively, the substrate SUB may include a quartz substrate, a synthetic quartz substrate, a calcium fluoride substrate, a fluorine-doped quartz substrate, a soda-lime glass substrate, a non-alkali glass substrate, etc. These may be used alone or in combination with each other.

The buffer layer BUF may be disposed on the substrate SUB. The buffer layer BUF may prevent diffusion of metal atoms or impurities from the substrate SUB to an upper structure (e.g., the first transistor TR1, the second transistor TR2, etc.). In addition, the buffer layer BUF may obtain the substantially uniform active layer ACT by controlling a heat transfer rate during a crystallization process for forming the active layer ACT. In addition, the buffer layer BUF may serve to improve flatness of a surface of the substrate SUB when the surface of the substrate SUB is not uniform. For example, the buffer layer BUF may include an inorganic insulating material. Examples of the inorganic insulating material that may be used as the buffer layer BUF may include silicon oxide (SiOₓ), silicon nitride (SiNₓ), silicon oxynitride (SiOₓN_{y}), etc. These may be used alone or in combination with each other. Alternatively, the buffer layer BUF may be omitted.

The first active pattern ACT1 may be disposed on the buffer layer BUF. The first active pattern ACT1 may include an oxide semiconductor, a silicon semiconductor, an organic semiconductor, etc. In an embodiment, the first active pattern ACT1 may include a silicon semiconductor. For example, the silicon semiconductor may include amorphous silicon, polycrystalline silicon, etc. The first active pattern ACT1 may include a first source area, a first drain area, and a first channel area positioned between the first source area and the first drain area.

The first gate insulating layer GI1 may be disposed on the first active pattern ACT1 and the buffer layer BUF. The first gate insulating layer GI1 may cover the first active pattern ACT1 on the buffer layer BUF and may be disposed along the profile of the first active pattern ACT1 with a substantially uniform thickness. Alternatively, the first gate insulating layer GI1 may sufficiently cover the first active pattern ACT1 on the buffer layer BUF, and may have a substantially flat upper surface without creating a step difference around the first active pattern ACT1. The first gate insulating layer GI1 may include an inorganic insulating material. Examples of the inorganic insulating material that may be used as the first gate insulating layer GI1 may include silicon oxide (SiOₓ), silicon nitride (SiNₓ), silicon oxynitride (SiOₓN_{y}), etc. These may be used alone or in combination with each other. The first gate insulating layer GI1 may electrically insulate the first active pattern ACT1 and the first gate electrode GE1.

The first gate electrode GE1 may be disposed on the first gate insulating layer GI1. The first gate electrode GE1 may overlap the first channel area of the first active pattern ACT1. The first gate electrode GE1 may include a metal, an alloy, a metal nitride, a conductive metal oxide, a transparent conductive material, etc. Examples of materials that may be used as the first gate electrode GE1 may include silver (Ag), an alloy including silver, molybdenum (Mo), an alloy including molybdenum, aluminum (Al), an alloy including aluminum, aluminum nitride (AIN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (“ITO”), indium zinc oxide (“IZO”), etc. These may be used alone or in combination with each other.

The second gate insulating layer GI2 may be disposed on the first gate insulating layer GI1. The second gate insulating layer GI2 may cover the first gate electrode GE1 on the first gate insulating layer GI1 and may be disposed along the profile of the first gate electrode GE1 with a substantially uniform thickness. Alternatively, the second gate insulating layer GI2 may sufficiently cover the first gate electrode GE1 on the first gate insulating layer GI1 and may have a substantially flat upper surface without creating a step difference around the first gate electrode GE1. The second gate insulating layer GI2 may include an inorganic insulating material. Examples of the inorganic insulating material that may be used as the second gate insulating layer GI2 may include silicon oxide (SiOₓ), silicon nitride (SiNₓ), silicon oxynitride (SiOₓN_{y}), etc. These may be used alone or in combination with each other. The second gate insulating layer GI2 may electrically insulate the first gate electrode GE1 and the second gate electrode GE2.

The second gate electrode GE2 may be disposed on the second gate insulating layer GI2. The second gate electrode GE2 may overlap the first gate electrode GE1 in a plan view. The second gate electrode GE2 may form a capacitor (e.g., a storage capacitor) together with the first gate electrode GE1. For example, the second gate electrode GE2 may include a metal, an alloy, a metal nitride, a conductive metal oxide, a transparent conductive material, etc. These may be used alone or in combination with each other.

The first inter-layer insulating layer ILDI may be disposed on the second gate insulating layer GI2. The first inter-layer insulating layer ILDI may cover the second gate electrode GE2 on the second gate insulating layer GI2 and may be disposed along the profile of the second gate electrode GE2 with a uniform thickness. Alternatively, the first inter-layer insulating layer ILD1 may sufficiently cover the second gate electrode GE2 on the second gate insulating layer GI2 and may have a substantially flat upper surface without creating a step difference around the second gate electrode GE2. The first inter-layer insulating layer ILD1 may include an inorganic insulating material. Examples of the inorganic insulating material that may be used as the first inter-layer insulating layer ILD1 may include silicon oxide (SiOₓ), silicon nitride (SiNₓ), silicon oxynitride (SiOₓN_{y}), etc. These may be used alone or in combination with each other.

The second active pattern ACT2 may be disposed on the first inter-layer insulating layer ILD1. The second active pattern ACT2 may include an oxide semiconductor, a silicon semiconductor, an organic semiconductor, etc. In an embodiment, the second active pattern ACT2 may include an oxide semiconductor. The oxide semiconductor may include binary compound (ABₓ), ternary compound (ABₓC_{y}), quaternary compound (ABₓC_{y}D_{z}), etc. including indium (In), zinc (Zn), gallium (Ga), tin (Sn), titanium (Ti), aluminum (Al), hafnium (Hf), zirconium (Zr), magnesium (Mg), etc. For example, the oxide semiconductor may include zinc oxide (ZnOₓ), gallium oxide (GaOₓ), tin oxide (SnOₓ), indium oxide (InOₓ), indium gallium oxide (“IGO”), indium zinc oxide (IZO), indium tin oxide (ITO), indium zinc tin oxide (“IZTO”), indium gallium zinc oxide (“IGZO”), etc. These may be used alone or in combination with each other. The second active pattern ACT2 may include a second source area, a second drain area, and a second channel area positioned between the second source area and the second drain area.

The third gate insulating layer GI3 may be disposed on the first inter-layer insulating layer ILD1. The third gate insulating layer GI3 may cover the second active pattern ACT2 on the first inter-layer insulating layer ILDI and may be disposed along the profile of the second active pattern ACT2 with a uniform thickness. Alternatively, the third gate insulating layer GI3 may sufficiently cover the second active pattern ACT2 on the first inter-layer insulating layer ILD1 and may have a substantially flat upper surface without creating a step difference around the second active pattern ACT2. The third gate insulating layer GI3 may include an inorganic insulating material. Examples of the inorganic insulating material that may be used as the third gate insulating layer GI3 may include silicon oxide (SiOₓ), silicon nitride (SiNₓ), silicon oxynitride (SiOₓN_{y}), etc. These may be used alone or in combination with each other. The third gate insulating layer GI3 may electrically insulate the second active pattern ACT2 and the third gate electrode GE3.

The third gate electrode GE3 may be disposed on the third gate insulating layer GI3. The third gate electrode GE3 may overlap the second channel area of the second active pattern ACT2. For example, the third gate electrode GE3 may include a metal, an alloy, a metal nitride, a conductive metal oxide, a transparent conductive material, etc. These may be used alone or in combination with each other.

The second inter-layer insulating layer ILD2 may be disposed on the third gate insulating layer GI3. The second inter-layer insulating layer ILD2 may sufficiently cover the third gate electrode GE3 on the third gate insulating layer GI3 and may have a substantially flat upper surface without creating a step difference around the third gate electrode GE3. Alternatively, the second inter-layer insulating layer ILD2 may cover the third gate electrode GE3 on the third gate insulating layer GI3 and may be disposed along the profile of the third gate electrode GE3 with a uniform thickness. The second inter-layer insulating layer ILD2 may include an inorganic insulating material. Examples of the inorganic insulating material that may be used as the second inter-layer insulating layer ILD2 may include silicon oxide (SiOₓ), silicon nitride (SiNₓ), silicon oxynitride (SiOₓN_{y}), etc. These may be used alone or in combination with each other. The second inter-layer insulating layer ILD2 may electrically insulate the third gate electrode GE3 and the source electrode SE. In addition, the second inter-layer insulating layer ILD2 may electrically insulate the third gate electrode GE3 and the drain electrode DE.

A first opening CNT1 may be defined in the first insulating layer group ILG1. For example, the first opening CNT1 may penetrate at least a portion of each of the first gate insulating layer GI1, the second gate insulating layer GI2, the first inter-layer insulating layer ILD1, the third gate insulating layer GI3, and the second inter-layer insulating layer ILD2. The first opening CNT1 may expose a portion of the first active pattern ACT1. A second opening CNT2 may be defined in the third gate insulating layer GI3 and the second inter-layer insulating layer ILD2. For example, the second opening CNT2 may penetrate at least a portion of each of the second inter-layer insulating layer ILD2 and the third gate insulating layer GI3. The second opening CNT2 may expose a portion of the second active pattern ACT2.

The first source-drain structure SDG1 and the second source-drain structure SDG2 may be disposed on the second inter-layer insulating layer ILD2. The first source-drain structure SDG1 may be connected to the first source area of the first active pattern ACT1 through the first opening CNT1 penetrating the first insulating layer group ILG1. The second source-drain structure SDG2 may be connected to the first drain area of the first active pattern ACT1 through the first opening CNT1 penetrating the first insulating layer group ILG1.

As illustrated in FIG. 3, the first source-drain structure SDG1 may include a first conductive layer SD1, an organic layer pattern OGL, and a second conductive layer SD2. The second source-drain structure SDG2 may have substantially the same structure as the first source-drain structure SDG1. Therefore, hereinafter, the description will focus on the first source-drain structure SDG1, and the description of the first source-drain structure SDG1 may replace the description of the second source-drain structure SDG2.

The first conductive layer SD1 may include a metal, an alloy, a metal nitride, a conductive metal oxide, a transparent conductive material, etc. These may be used alone or in combination with each other. In an embodiment, the first conductive layer SD1 may be formed through a sputtering process.

In order to improve the resolution of the display device DD, a diameter of the first opening CNT1 may be designed to be relatively small. Here, the diameter of the first opening

CNT1 may be defined as a maximum length of the first opening CNT1 in the first direction DR1 or a maximum length of the first opening CNT1 in the second direction DR2. For example, a first diameter D1 of the first opening CNT1 may be about 1.7 micrometers to about 2.0 micrometers. As the first diameter D1 of the first opening CNT1 is designed to be relatively small, an aspect ratio of the first opening CNT1 may be relatively large. Here, the aspect ratio of the first opening CNTI may be defined as a ratio of a height of the first opening CNT1 to the diameter of the first opening CNT1. The height of the first opening CNT1 may be defined as a length of the first opening CNT1 in the third direction DR3.

As the aspect ratio of the first opening CNT1 becomes relatively large, in the process of forming the first conductive layer SD1 through the sputtering process, the first conductive layer SD1 may be broken into a first conductive pattern SD1-P1 and a second conductive pattern SD1-P2. That is, the first conductive layer SD1 may include the first conductive pattern SD1-P1 and the second conductive pattern SD1-P2 that are disconnected from each other. Accordingly, the first conductive pattern SD1-P1 and the second conductive pattern SD1-P2 may define an undercut structure UC in the first opening CNT1. The undercut structure UC may be defined as a disconnected structure between the first conductive pattern SD1-P1 and the second conductive pattern SD1-P2 in an area overlapping the first opening CNT1 in a plan view.

The first conductive pattern SD1-P1 may be disposed on the first insulating layer group ILG1. Specifically, the first conductive pattern SD1-P1 may be disposed on the second inter-layer insulating layer ILD2. The first conductive pattern SD1-P1 may contact a side surface of the first insulating layer group ILG1 defining the first opening CNT1.

In this specification, an upper surface of the first conductive pattern SD1-P1 may be defined as a surface positioned at the highest level from an upper surface of the substrate SUB among surfaces of the first conductive pattern SD1-P1. A lower surface of the first conductive pattern SD1-P1 may be defined as a surface positioned at the lowest level from the upper surface of the substrate in the first opening CNT1 among the surfaces of the first conductive pattern SD1-P1. A side surface of the first conductive pattern SD1-P1 may be defined as a surface connecting a first edge EG1 of the upper surface of the first conductive pattern SD1-P1 and a second edge EG2 of the lower surface of the first conductive pattern SD1-P1. For example, as illustrated in FIG. 3, the side surface of the first conductive pattern SD1-P1 may include a stepped structure in cross-section. However, the present disclosure is not limited to thereto. For another example, the side surface of the first conductive pattern SD1-P1 may have a diagonal shape in cross-section.

In an embodiment, the first edge EG1 of the upper surface of the first conductive pattern SD1-P1 may protrude further than the second edge EG2 of the lower surface of the first conductive pattern SD1-P1 in a direction toward a center of the first opening CNT1. That is, in the process of forming the first conductive pattern SD1-P1 and the second conductive pattern SD1-P2 through the sputtering method, the first edge EG1 may be protrude further than the second edge EG2 in the direction toward the center of the first opening CNT1.

In the first opening CNT1 (or, in an area overlapping the first opening CNT1 in a plan view), a length of the upper surface of the first conductive pattern SD1-P1 in the first direction DR1 may be greater than a length of the lower surface of the conductive pattern SD1-P1 in the first direction DR1.

The second conductive pattern SD1-P2 may be disposed on the first active pattern ACT1 in the first opening CNT1. A height of an upper surface of the second conductive pattern SD1-P2 at the center of the first opening CNT1 may be greater than a height of the upper surface of the second conductive pattern SD1-P2 at an edge of the first opening CNT1. Here, the height of the upper surface of the second conductive pattern SD1-P2 may be defined as a straight-line distance in the third direction DR3 from an upper surface of the first active pattern

ACT1 to the upper surface of the second conductive pattern SD1-P2. In the process of forming the first conductive pattern SD1-P1 and the second conductive pattern SD1-P2 through the sputtering method, the first edge EG1 may protrude further than the second edge EG2 in the direction toward the center of the first opening CNT1. Accordingly, in an area overlapping the upper surface of the first conductive pattern SD1-P1 in the first opening CNT1 in a plan view (or, an area adjacent to the edge of the first opening CNT1), the second conductive pattern SD1-P2 may be deposited in a relatively small amount. As a result, the height of the upper surface of the second conductive pattern SD1-P2 at the center of the first opening CNT1 may be greater than the height of the upper surface of the second conductive pattern SD1-P2 at the edge of the first opening CNT1.

The organic layer pattern OGL may be disposed in the first opening CNT1 and May contact the first conductive pattern SD1-P1 and the second conductive pattern SD1-P2. In an embodiment, the organic layer pattern OGL may fill a space defined by the undercut structure UC. In other words, the organic layer pattern OGL may fill a disconnected space between the first conductive pattern SD1-P1 and the second conductive pattern SD1-P2 in an area overlapping the upper surface of the first conductive pattern SD1-P1 in the first opening CNT1 in a plan view. Accordingly, the organic layer pattern OGL may connect the first conductive patterns SD1-P1 and the second conductive patterns SD1-P2 that are disconnected from each other. As the organic layer pattern OGL fills the space defined by the undercut structure UC, the organic layer pattern OGL may cover a stepped structure of the side surface of the first conductive pattern SD1-P1.

The organic layer pattern OGL may expose a portion of the second conductive pattern SD1-P2. Specifically, the organic layer pattern OGL may be disposed to overlap the upper surface of the first conductive pattern SD1-P1 in the first opening CNT1 in a plan view, and may expose a portion of the upper surface of the second conductive pattern SD1-P2.

In an embodiment, the organic layer pattern OGL may include a positive photosensitive organic material. For example, the organic layer pattern OGL may include photoresist. However, the present disclosure is not limited thereto.

In another embodiment, the organic layer pattern OGL may include a non-photosensitive organic material. For example, the organic layer pattern OGL may include polyacryl-based resin, polyimide-based resin, polyamide-based resin, siloxane-based resin, acryl-based resin, epoxy-based resin, etc. These may be used alone or in combination with each other.

The second conductive layer SD2 may cover the organic layer pattern OGL and the side surface of the first conductive pattern SD1-P1, and may contact the second conductive pattern SD1-P2. Specifically, the second conductive layer SD2 may cover the upper surface of the second conductive pattern SD1-P2 exposed from the organic layer pattern OGL. Accordingly, the second conductive layer SD2 may be electrically connected to the second conductive patterns SD1-P2. The second conductive layer SD2 may include a metal, an alloy, a metal nitride, a conductive metal oxide, a transparent conductive material, etc. These may be used alone or in combination with each other. In an embodiment, the second conductive layer SD2 may be formed through a sputtering process.

In an embodiment, the second conductive layer SD2 may continuously extend in the first opening CNT1. That is, as the organic layer pattern OGL fills the space defined by the undercut structure UC, the second conductive layer SD2 may continuously extend in the first opening CNT1 without being disconnected.

When the first conductive layer SD1 does not extend continuously in the first opening CNT1 and is disconnected into the first conductive pattern SD1-P1 and the second conductive pattern SD1-P2, the first conductive pattern SD1-P1 of the first conductive layer SD1 may not be electrically connected to the first source area of the first active pattern ACT1. In other words, since the first conductive pattern SD1-P1 and the second conductive pattern SD1-P2 are not electrically connected to each other, the first conductive pattern SD1-P1 of the first conductive layer SD1 may not be electrically connected to the first source area of the first active pattern ACT1.

In order to compensate for such connection failure, the display device DD according to an embodiment of the present disclosure may include the organic layer pattern OGL that fills the disconnected space between the first conductive pattern SD1-P1 and the second conductive pattern SD1-P2 in the first opening CNT1.

As the organic layer pattern OGL fills the disconnected space between the first conductive pattern SD1-P1 and the second conductive pattern SD1-P2 in the first opening

CNT1, the second conductive layer SD2 may extend continuously in the first opening CNT1 without being disconnected. Accordingly, the second conductive layer SD2 may be electrically connected to the first source area of the first active pattern ACT1 through the second conductive pattern SD1-P2. That is, even if a disconnection occurs in the first conductive layer SD1, the second conductive layer SD2 may be electrically connected to the first source area of the first active pattern ACT1.

As illustrated in FIG. 2, the source electrode SE and the drain electrode DE may be disposed on the second inter-layer insulating layer ILD2. The source electrode SE may be connected to the second source area of the second active pattern ACT2 through the second opening CNT2 penetrating the third gate insulating layer GI3 and the second inter-layer insulating layer ILD2. The drain electrode DE may be connected to the second drain area of the second active pattern ACT2 through the second opening CNT2 penetrating the third gate insulating layer GI3 and the second inter-layer insulating layer ILD2. Each of the source electrode SE and the drain electrode DE may include a metal, an alloy, a metal nitride, a conductive metal oxide, a transparent conductive material, etc. These may be used alone or in combination with each other.

In an embodiment, each of the source electrode SE and the drain electrode DE may be formed through the same process using the same material as the first conductive layer SD1.

In another embodiment, each of the source electrode SE and the drain electrode DE may include a first layer formed using the same material as the first conductive layer SD1 and a second layer disposed on the first layer and formed using the same material as the second conductive layer SD2.

In an embodiment, the organic layer pattern OGL may be disposed in the first opening CNT1 and may not be disposed in the second opening CNT2. Since the first active pattern ACT1 is disposed under the second active pattern ACT2, a first height H1 of the first opening

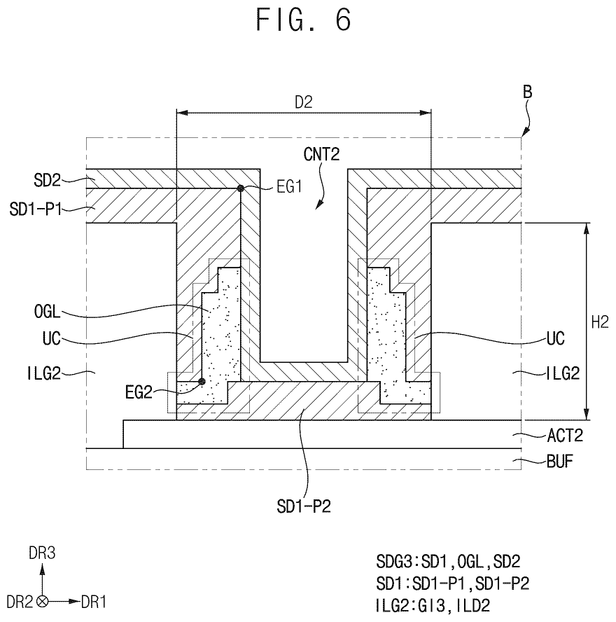

CNT1 may be greater than a second height (e.g., a second height H2 of FIG. 6) of the second opening CNT2. In other words, the aspect ratio of the first opening CNT1 may be greater than the aspect ratio of the second opening CNT2. Therefore, the organic layer pattern OGL may be disposed in the first opening CNT1, where the probability of a disconnection failure of the first conductive layer SD1 is relatively high. In addition, the organic layer pattern OGL may not be disposed in the second opening CNT2, where the probability of the disconnection failure of the first conductive layer SD1 is relatively low. However, the present disclosure is not limited thereto, and the organic layer pattern OGL may also be disposed in the second opening CNT2 in another embodiment. This will be described in more detail below with reference to FIG. 6.

Accordingly, the first transistor TRI including the first active pattern ACT1, the first gate electrode GE1, the first source-drain structure SDG1, and the second source-drain structure SDG2 may be formed. In addition, the second transistor TR2 including the second active pattern ACT2, the third gate electrode GE3, the source electrode SE, and the drain electrode DE may be formed.

The first via-insulating layer VIA1 may be disposed on the second inter-layer insulating layer ILD2. The first via-insulating layer VIA1 may be disposed with a relatively thick thickness to sufficiently cover the source electrode SE, the drain electrode DE, the first source-drain structure SDG1, and the second source-drain structure SDG2. A third opening may be defined in the first via-insulating layer VIA1. For example, the third opening may penetrate at least a portion of the first via-insulating layer VIA1. The third opening may expose a portion of the second source-drain structure SDG2. Specifically, the third opening may expose a portion of the second conductive layer SD2 of the second source-drain structure SDG2. The first via-insulating layer VIA1 may include an organic insulating material. Examples of the organic insulating material that may be used as the first via-insulating layer VIA1 may include photoresist, polyacryl-based resin, polyimide-based resin, polyamide-based resin, siloxane-based resin, acryl-based resin, epoxy-based resin, etc. These may be used alone or in combination with each other.

The connection electrode CNE may be disposed on the first via-insulating layer VIA1. The connection electrode CNE may be connected to the second conductive layer SD2 of the second source-drain structure SDG2 through the third opening penetrating the first via-insulating layer VIA1. Accordingly, the connection electrode CNE may electrically connect the first transistor TRI and the light emitting element LD. For example, the connection electrode CNE may include a metal, an alloy, a metal nitride, a conductive metal oxide, a transparent conductive material, etc. These may be used alone or in combination with each other.

The second via-insulating layer VIA2 may be disposed on the first via-insulating layer VIA1. The second via-insulating layer VIA2 may be disposed with a relatively thick thickness to sufficiently cover the connection electrode CNE. A fourth opening may be defined in the second via-insulating layer VIA2. The fourth opening may penetrate at least a portion of the second via-insulating layer VIA2. The fourth opening may expose a portion of the connection electrode CNE. The second via-insulating layer VIA2 may include an organic insulating material. Examples of the organic insulating material that may be used as the second via-insulating layer VIA2 may include photoresist, polyacryl-based resin, polyimide-based resin, polyamide-based resin, siloxane-based resin, acryl-based resin, epoxy-based resin, etc. These may be used alone or in combination with each other.

The pixel electrode PE may be disposed on the second via-insulating layer VIA2. The pixel electrode PE may be connected to the connection electrode CNE through the fourth opening penetrating the second via-insulating layer VIA2. For example, the pixel electrode PE may include a metal, an alloy, a metal nitride, a conductive metal oxide, a transparent conductive material, etc. These may be used alone or in combination with each other. For example, the pixel electrode PE may serve as an anode electrode.

The pixel defining layer PDL may be disposed on the second via-insulating layer VIA2. The pixel defining layer PDL may cover an edge of the pixel electrode PE and expose a portion of the pixel electrode PE. The pixel defining layer PDL may include an organic insulating material. Examples of the organic insulating material that may be used as the pixel defining layer PDL may include photoresist, polyacryl-based resin, polyimide-based resin, polyamide-based resin, siloxane-based resin, acryl-based resin, epoxy-based resin, etc. These may be used alone or in combination with each other.

The light emitting layer EML may be disposed on the pixel electrode PE. The light emitting layer EML may include an organic material that emits light of a preset color. For example, the light emitting layer EML may include an organic light emitting material including a fluorescent or phosphorescent material that emits red, green, blue, or white light.

The common electrode CTE may be disposed on the pixel defining layer PDL and the light emitting layer EML. The common electrode CTE may include a metal, an alloy, a metal nitride, a conductive metal oxide, a transparent conductive material, etc. These may be used alone or in combination with each other. For example, the common electrode CTE may serve as a cathode electrode.

Accordingly, the light emitting element LD including the pixel electrode PE, the light emitting layer EML, and the common electrode CTE may be formed.

The encapsulation layer TFE may be disposed on the common electrode CTE. The encapsulation layer TFE may prevent impurities, moisture, etc. from penetrating into the light emitting element LD from the outside. The encapsulation layer TFE may include at least one inorganic encapsulation layer and at least one organic encapsulation layer. For example, the inorganic encapsulation layer may include silicon oxide (SiOₓ), silicon nitride (SiNₓ), silicon oxynitride (SiOₓN_{y}), etc. These may be used alone or in combination with each other. For example, the organic encapsulation layer may include a cured polymer such as polyacrylate.

Although the display device DD of the present disclosure is described by limiting the organic light emitting display (OLED) device, the configuration of the present disclosure is not limited thereto. In other embodiments, the display device DD may include a liquid crystal display (LCD) device, a field emission display (“FED”) device, a plasma display panel (PDP) device, an electrophoretic image display (“EPD”) device, an inorganic light emitting display (“ILED”) device, or a quantum dot display device.

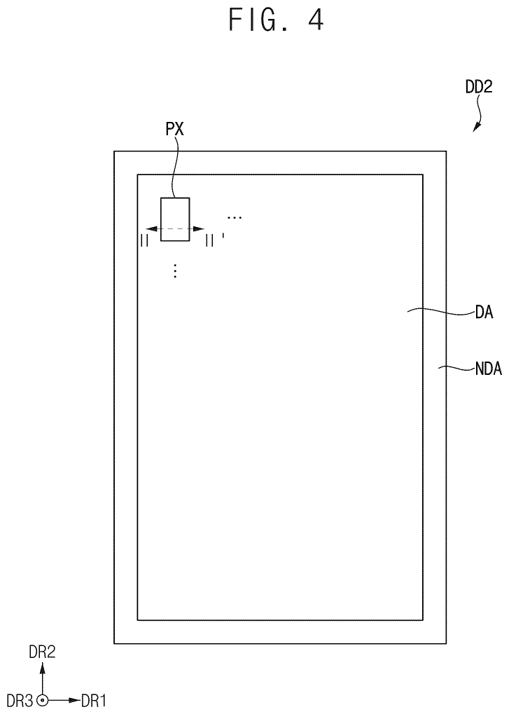

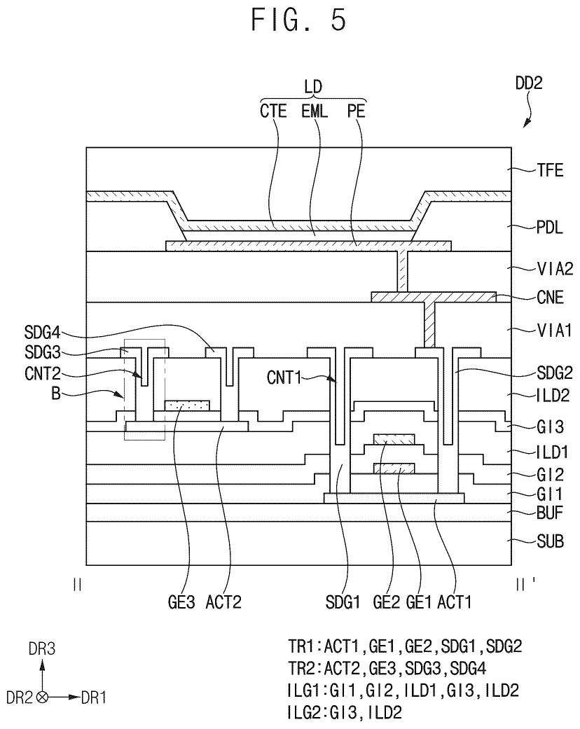

FIG. 4 is a plan view illustrating a display device according to another embodiment of the present disclosure. FIG. 5 is a cross-sectional view taken along line II-II′ of FIG. 4. FIG. 6 is an enlarged cross-sectional view of area ‘B’ of FIG. 5.

Referring to FIGS. 4, 5, and 6, a display device DD2 according to another embodiment of the present disclosure may include the substrate SUB, the buffer layer BUF, the first transistor TR1, a second transistor TR2, the first insulating layer group ILG1, a second insulating layer group ILG2, the first via-insulating layer VIA1, the second via-insulating layer VIA2, the connecting electrode CNE, the pixel defining layer PDL, the light emitting element LD, and the encapsulation layer TFE.

The first transistor TRI may include the first active pattern ACT1, the first gate electrode GE1, the first source-drain structure SDG1, and the second source-drain structure SDG2. The second transistor TR2 may include the second active pattern ACT2, the third gate electrode GE3, a third source-drain structure SDG3, and a fourth source-drain structure SDG4. The first insulating layer group ILG1 may include the first gate insulating layer GI1, the second gate insulating layer GI2, the first inter-layer insulating layer ILD1, the third gate insulating layer GI3, and the second inter-layer insulating layer ILD2. The second insulating layer group ILG2 may include the third gate insulating layer GI3 and the second inter-layer insulating layer ILD2. The light emitting element LD may include the pixel electrode PE, the light emitting layer EML, and the common electrode CTE.

The display device DD2 may be substantially the same as the display device DD described with reference to FIGS. 1, 2, and 3, except that the display device DD2 includes the third source-drain structure SDG3 and the fourth source-drain structure SDG4 that are connected to the second active pattern ACT2. Hereinafter, the descriptions overlapping the descriptions of the display device DD described with reference to FIGS. 1, 2, and 3 will be omitted or simplified.

The second active pattern ACT2 may be disposed on the first inter-layer insulating layer ILD1. In an embodiment, the second active pattern ACT2 may include an oxide semiconductor. The second active pattern ACT2 may include a second source area, a second drain area, and a second channel area positioned between the second source area and the second drain area.

The third gate insulating layer GI3 may be disposed on the first inter-layer insulating layer ILD1, and the third gate electrode GE3 may be disposed on the third gate insulating layer GI3. The third gate electrode GE3 may overlap the second channel area of the second active pattern ACT2. The second inter-layer insulating layer ILD2 may be disposed on the third gate insulating layer GI3.

The first opening CNT1 may be defined in the first insulating layer group ILG1. For example, the first opening CNT1 may penetrate at least a portion of each of the first gate insulating layer GI1, the second gate insulating layer GI2, the first inter-layer insulating layer ILD1, the third gate insulating layer GI3, and the second inter-layer insulating layer ILD2. The first opening CNT1 may expose a portion of the first active pattern ACT1.

The second opening CNT2 may be defined in the second insulating layer group ILG2. For example, the second opening CNT2 may penetrate at least a portion of each of the third gate insulating layer GI3 and the second inter-layer insulating layer ILD2. The second opening CNT2 may expose a portion of the second active pattern ACT2.

The first source-drain structure SDG1 and the second source-drain structure SDG2 may be disposed on the second inter-layer insulating layer ILD2. The first source-drain structure SDG1 may be connected to the first source area of the first active pattern ACT1 through the first opening CNT1 penetrating the first insulating layer group ILG1. The second source-drain structure SDG2 may be connected to the first drain area of the first active pattern ACT1 through the first opening CNT1 penetrating the first insulating layer group ILG1.

The third source-drain structure SDG3 and the fourth source-drain structure SDG4 may be disposed on the second inter-layer insulating layer ILD2. The third source-drain structure SDG3 may be connected to the second source area of the second active pattern ACT2 through the second opening CNT2 penetrating the second insulating layer group ILG2. The fourth source-drain structure SDG4 may be connected to the second drain area of the second active pattern ACT2 through the second opening CNT2 penetrating the second insulating layer group ILG2.

As illustrated in FIG. 6, the third source-drain structure SDG3 may include a first conductive layer SD1, an organic layer pattern OGL, and a second conductive layer SD2. The fourth source-drain structure SDG4 may have substantially the same structure as the third source-drain structure SDG3. Therefore, hereinafter, the description will focus on the third source-drain structure SDG3, and the description of the third source-drain structure SDG3 may replace the description of the fourth source-drain structure SDG4.

In an embodiment, the first conductive layer SD1 may be formed through a sputtering process. In the process of forming the first conductive layer SD1 through the sputtering process, the first conductive layer SD1 may be broken into a first conductive pattern SD1-P1 and a second conductive pattern SD1-P2. That is, the first conductive layer SD1 may include the first conductive pattern SD1-P1 and the second conductive pattern SD1-P2 that are disconnected from each other. Accordingly, the first conductive pattern SD1-P1 and the second conductive pattern SD1-P2 may define an undercut structure UC in the second opening CNT2. The undercut structure UC may be defined as a disconnected structure between the first conductive pattern SD1-P1 and the second conductive pattern SD1-P2 in an area overlapping the second opening CNT2 in a plan view.

The first conductive pattern SD1-P1 may be disposed on the second insulating layer group ILG2. Specifically, the first conductive pattern SD1-P1 may be disposed on the second inter-layer insulating layer ILD2. The first conductive pattern SD1-P1 may contact a side surface of the second insulating layer group ILG2 defining the second opening CNT2.

An upper surface of the first conductive pattern SD1-P1 may be defined as a surface positioned at the highest level from an upper surface of the substrate SUB among surfaces of the first conductive pattern SD1-P1. A lower surface of the first conductive pattern SD1-P1 may be defined as a surface positioned at the lowest level from the upper surface of the substrate in the second opening CNT2 among the surfaces of the first conductive pattern SD1-P1. A side surface of the first conductive pattern SD1-P1 may be defined as a surface connecting a first edge EG1 of the upper surface of the first conductive pattern SD1-P1 and a second edge EG2 of the lower surface of the first conductive pattern SD1-P1. For example, as illustrated in FIG. 6, the side surface of the first conductive pattern SD1-P1 may include a stepped structure in cross-section. However, the present disclosure is not limited to thereto.

In an embodiment, the first edge EG1 of the upper surface of the first conductive pattern SD1-P1 may protrude further than the second edge EG2 of the lower surface of the first conductive pattern SD1-P1 in a direction toward a center of the second opening CNT2. That is, in the process of forming the first conductive pattern SD1-P1 and the second conductive pattern SD1-P2 through the sputtering method, the first edge EG1 may be protrude further than the second edge EG2 in the direction toward the center of the second opening CNT2.

The second conductive pattern SD1-P2 may be disposed on the second active pattern ACT2 in the second opening CNT2. A height of an upper surface of the second conductive pattern SD1-P2 at the center of the second opening CNT2 may be greater than a height of the upper surface of the second conductive pattern SD1-P2 at an edge of the second opening CNT2. In the process of forming the first conductive pattern SD1-P1 and the second conductive pattern SD1-P2 through the sputtering method, the first edge EG1 may protrude further than the second edge EG2 in the direction toward the center of the second opening CNT2. Accordingly, in an area overlapping the upper surface of the first conductive pattern SD1-P1 in the second opening CNT2 in a plan view (or, an area adjacent to the edge of the second opening CNT2), the second conductive pattern SD1-P2 may be deposited in a relatively small amount.

In an embodiment, a second diameter D2 of the second opening CNT2 may be the same as the first diameter (e.g., the first diameter D1 of FIG. 3) of the first opening CNT1. Here, the second diameter D2 of the second opening CNT2 may be defined as a maximum length of the second opening CNT2 in the first direction DR1 or a maximum length of the second opening CNT2 in the second direction DR2. For example, the second diameter D2 of the second opening CNT2 may be about 1.7 micrometers to about 2.0 micrometers.

In an embodiment, a second height H2 of the second opening CNT2 may be smaller than the first height (e.g., the first height H1 of FIG. 3) of the first opening CNT1. The second opening CNT2 may be formed across the third gate insulating layer GI3 and the second inter-layer insulating layer ILD2, and the first opening CNT1 may be formed across the first gate insulating layer GI1, the second gate insulating layer GI2, the first inter-layer insulating layer ILD1, the third gate insulating layer GI3, and the second inter-layer insulating layer ILD2. Accordingly, the second height H2 may be smaller than the first height. As a result, the aspect ratio of the second opening CNT2 may be smaller than the aspect ratio of the first opening CNT1.

The organic layer pattern OGL may be disposed in the second opening CNT2 and may contact the first conductive pattern SD1-P1 and the second conductive pattern SD1-P2. In an embodiment, the organic layer pattern OGL may fill a space defined by the undercut structure UC. In other words, the organic layer pattern OGL may fill a disconnected space between the first conductive pattern SD1-P1 and the second conductive pattern SD1-P2 in an area overlapping the upper surface of the first conductive pattern SD1-P1 in the second opening CNT2 in a plan view. Accordingly, the organic layer pattern OGL may connect the first conductive patterns SD1-P1 and the second conductive patterns SD1-P2 that are disconnected from each other. As the organic layer pattern OGL fills the space defined by the undercut structure UC, the organic layer pattern OGL may cover a stepped structure of the side surface of the first conductive pattern SD1-P1.

The organic layer pattern OGL may expose a portion of the second conductive pattern SD1-P2. Specifically, the organic layer pattern OGL may be disposed to overlap the upper surface of the first conductive pattern SD1-P1 in the second opening CNT2 in a plan view, and may expose a portion of the upper surface of the second conductive pattern SD1-P2.

In an embodiment, the organic layer pattern OGL may be disposed in the first opening CNT1 and may be disposed in the second opening CNT2.

The second conductive layer SD2 may cover the organic layer pattern OGL and the side surface of the first conductive pattern SD1-P1, and may contact the second conductive pattern SD1-P2. Specifically, the second conductive layer SD2 may cover the upper surface of the second conductive pattern SD1-P2 exposed from the organic layer pattern OGL. Accordingly, the second conductive layer SD2 may be electrically connected to the second conductive patterns SD1-P2. In an embodiment, the second conductive layer SD2 may be formed through a sputtering process.

In an embodiment, the second conductive layer SD2 may continuously extend in the second opening CNT2. That is, as the organic layer pattern OGL fills the space defined by the undercut structure UC, the second conductive layer SD2 may continuously extend in the second opening CNT1 without being disconnected. Accordingly, the second conductive layer SD2 may be electrically connected to the second source area of the second active pattern ACT2 through the second conductive pattern SD1-P2. That is, even if a disconnection occurs in the first conductive layer SD1, the second conductive layer SD2 may be electrically connected to the second source area of the second active pattern ACT2.

Accordingly, the first transistor TRI including the first active pattern ACT1, the first gate electrode GE1, the first source-drain structure SDG1, and the second source-drain structure SDG2 may be formed. In addition, the second transistor TR2 including the second active pattern ACT2, the third gate electrode GE3, the third source-drain structure SDG3, and the fourth source-drain structure SDG4 may be formed.

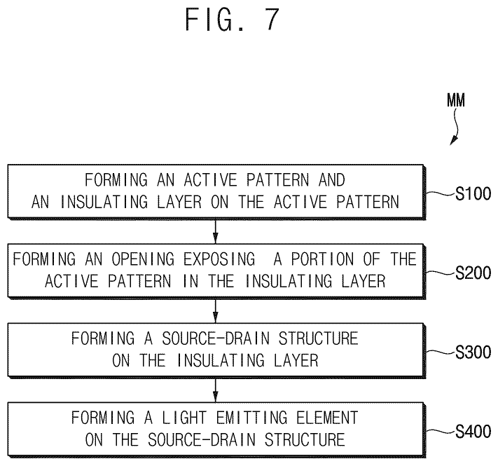

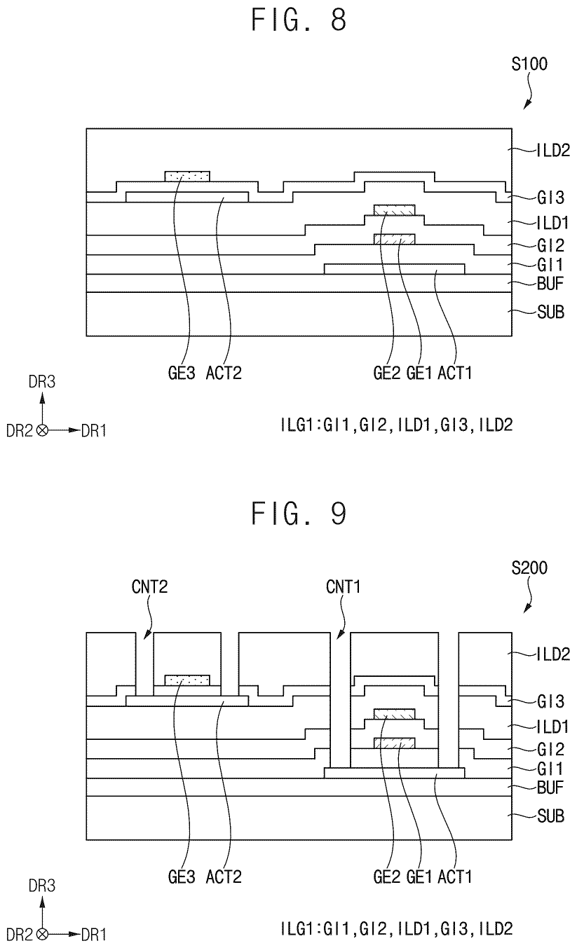

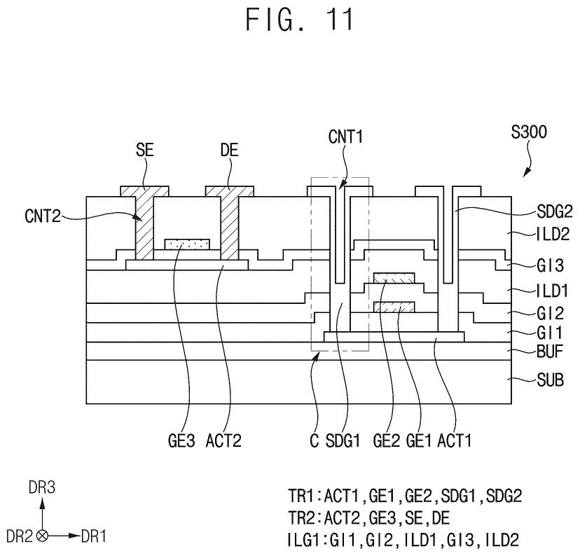

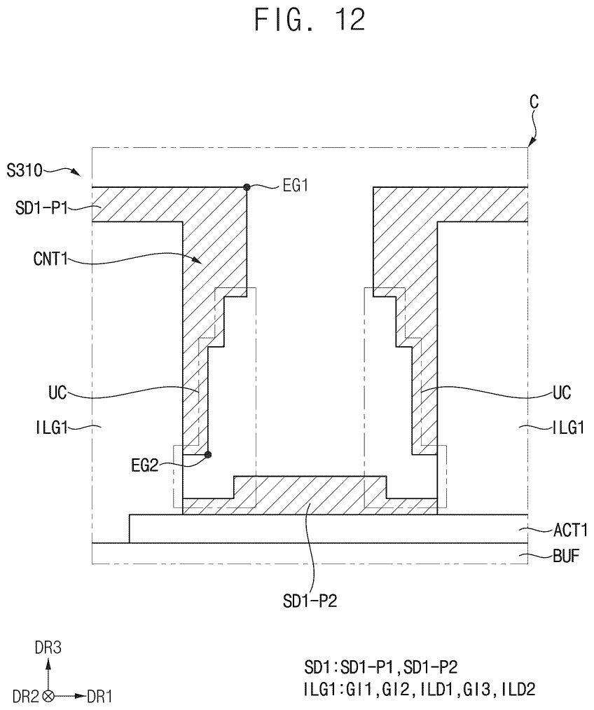

FIG. 7 is a flowchart of a method of manufacturing a display device according to an embodiment of the present disclosure. FIGS. 8, 9, 10, 11, 12, 13, 14, 15, 16, and 17 are views illustrating the method of manufacturing the display device of FIG. 7. For example, FIGS. 8 to 17 are views for explaining the method of manufacturing the display device DD described with reference to FIGS. 1 to 3. The display device DD2 described with reference to FIGS. 4 to 6 may be substantially the same as the display device DD described with reference to FIGS. 1 to 3, except that the display device DD2 includes the third source-drain structure SDG3 and the fourth source-drain structure SDG4 that are connected to the second active pattern ACT2. Accordingly, the description of the method of manufacturing the display device DD may replace the description of a method of manufacturing the display device DD2.

Referring to FIG. 7, a method MM of manufacturing a display device according to an embodiment of the present disclosure may include: forming an active pattern and an insulating layer on the active pattern (S100), forming an opening exposing a portion of the active pattern in the insulating layer (S200), forming a source-drain structure on the insulating layer (S300), and forming a light emitting element on the source-drain structure (S400).

Referring to FIG. 8, a first active pattern ACT1 may be formed on a substrate SUB, and a first insulating layer group ILG1 may be formed on the first active pattern ACT1 (S100). The first insulating layer group ILG1 may include a first gate insulating layer GI1, a second gate insulating layer GI2, a first inter-layer insulating layer ILD1, a third gate insulating layer GI3, and a second inter-layer insulating layer ILD2.

A buffer layer BUF may be formed on the substrate SUB, and the first active pattern ACT1 may be formed on the buffer layer BUF. The first gate insulating layer GI1 covering the first active pattern ACT1 may be formed on the buffer layer BUF. A first gate electrode GE1 may be formed on the first gate insulating layer GI1.

The second gate insulating layer GI2 covering the first gate electrode GE1 may be formed on the first gate insulating layer GI1. A second gate electrode GE2 may be formed on the second gate insulating layer GI2.

The first inter-layer insulating layer ILDI covering the second gate electrode GE2 may be formed on the second gate insulating layer GI2. A second active pattern ACT2 may be formed on the first inter-layer insulating layer ILD1. That is, the second active pattern ACT2 may be formed on the first active pattern ACT1.

The third gate insulating layer GI3 covering the second active pattern ACT2 may be formed on the first inter-layer insulating layer ILD1. A third gate electrode GE3 may be formed on the third gate insulating layer GI3. The second inter-layer insulating layer ILD2 covering the third gate electrode GE3 may be formed on the third gate insulating layer GI3.

Referring to FIG. 9, a first opening CNT1 exposing a portion of the first active pattern ACT1 may be formed in the first insulating layer group ILG1, and a second opening CNT2 exposing a portion of the second active pattern ACT2 may be formed in the third gate insulating layer GI3 and the second inter-layer insulating layer ILD2 (S200). Since the first active pattern ACT1 is disposed under the second active pattern ACT2, the aspect ratio of the first opening CNT1 may be greater than the aspect ratio of the second opening CNT2.

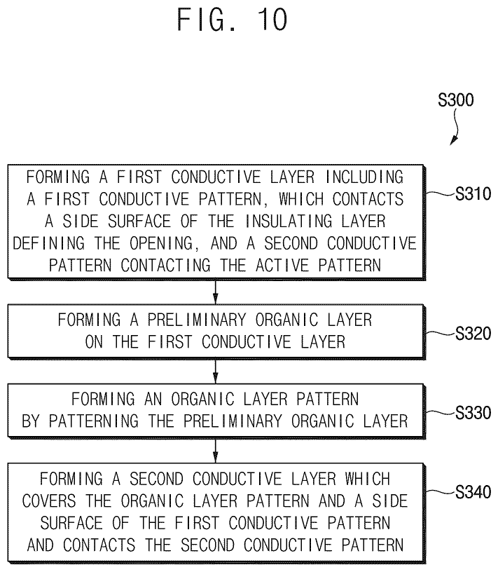

Referring to FIGS. 10, 11, 12, 13, 14, 15, and 16, forming a first source-drain structure SDG1 and a second source-drain structure SDG2 on the first insulating layer group ILG1 (S300) may include forming a first conductive layer SD1 including a first conductive pattern SD1-P1 which contacts a side surface of the first insulating layer group ILG1 defining the first opening CNT1, and a second conductive pattern SD1-P2 contacting the first active pattern ACT1 (S310), forming a preliminary organic layer POGL on the first conductive layer SD1 (S320), forming an organic layer pattern OGL by patterning the preliminary organic layer POGL (S330), and forming a second conductive layer SD2 which covers the organic layer pattern OGL and a side surface of the first conductive pattern SD1-P1 and contacts the second conductive pattern SD1-P2 (S340).

As illustrated in FIG. 12, the first conductive layer SD1 including the first conductive pattern SD1-P1 which contacts the side surface of the first insulating layer group ILG1 defining the first opening CNT1, and the second conductive pattern SD1-P2 contacting the first active pattern ACT1 may be formed (S310). In an embodiment, the first conductive layer SD1 may be formed through a sputtering process.

In the process of forming the first conductive layer SD1 through the sputtering process, the first conductive layer SD1 may be broken into the first conductive pattern SD1-P1 and the second conductive pattern SD1-P2. That is, the first conductive layer SD1 may include the first conductive pattern SD1-P1 and the second conductive pattern SD1-P2 that are disconnected from each other. Accordingly, the first conductive pattern SD1-P1 and the second conductive pattern SD1-P2 may define an undercut structure UC in the first opening CNT1. The undercut structure UC may be defined as a disconnected structure between the first conductive pattern SD1-P1 and the second conductive pattern SD1-P2 in an area overlapping the first opening CNT1 in a plan view.

The first conductive pattern SD1-P1 may be formed on the first insulating layer group ILG1. The first conductive pattern SD1-PI may contact the side surface of the first insulating layer group ILG1 that defines the first opening CNT1.

In an embodiment, a first edge EG1 of an upper surface of the first conductive pattern SD1-P1 may protrude further than a second edge EG2 of a lower surface of the first conductive pattern SD1-P1 in a direction toward a center of the first opening CNT1. That is, in the process of forming the first conductive pattern SD1-P1 and the second conductive pattern SD1-P2 through the sputtering method, the first edge EG1 may be protrude further than the second edge EG2 in the direction toward the center of the first opening CNT1.

The second conductive pattern SD1-P2 may be formed on the first active pattern ACT1 in the first opening CNT1. A height of an upper surface of the second conductive pattern SD1-P2 at the center of the first opening CNT1 may be greater than a height of the upper surface of the second conductive pattern SD1-P2 at an edge of the first opening CNT1.

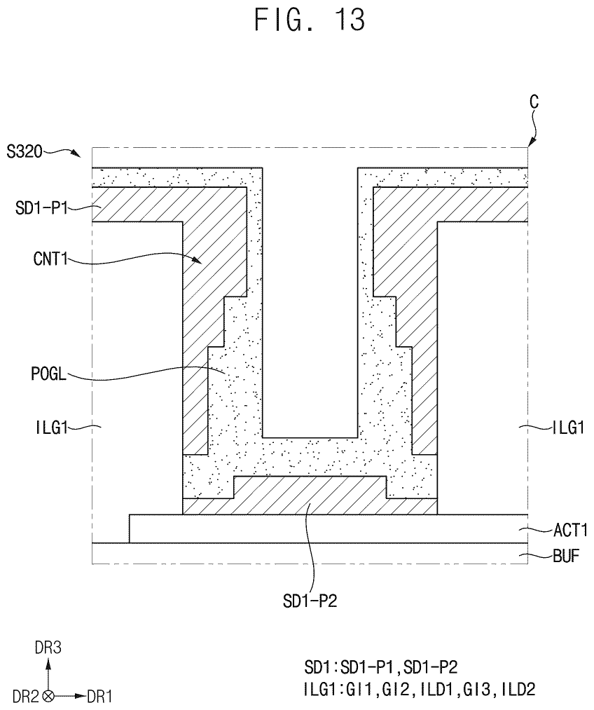

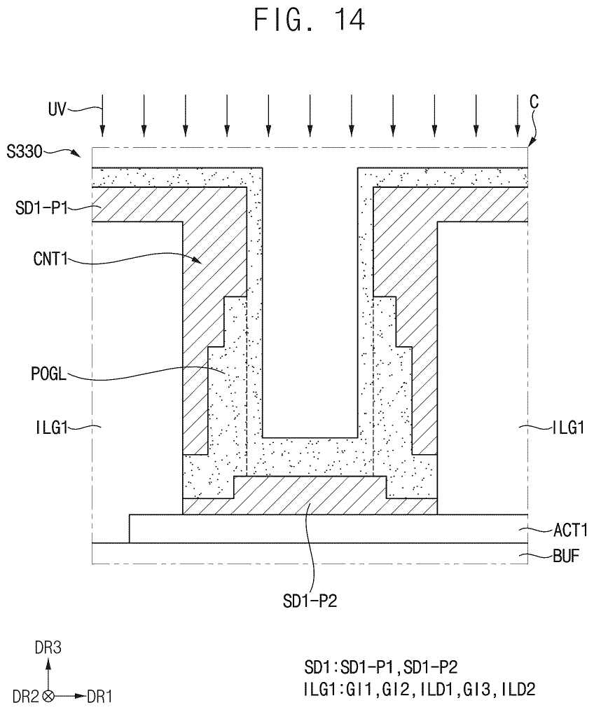

As illustrated in FIG. 13, the preliminary organic layer POGL may be formed on the first conductive layer SD1 (S320). The preliminary organic layer POGL may be formed to cover the first conductive pattern SD1-Pl and the second conductive pattern SD1-P2. In an embodiment, the preliminary organic layer POGL may include a positive photosensitive organic material. In another embodiment, the preliminary organic layer POGL may include a non-photosensitive organic material.

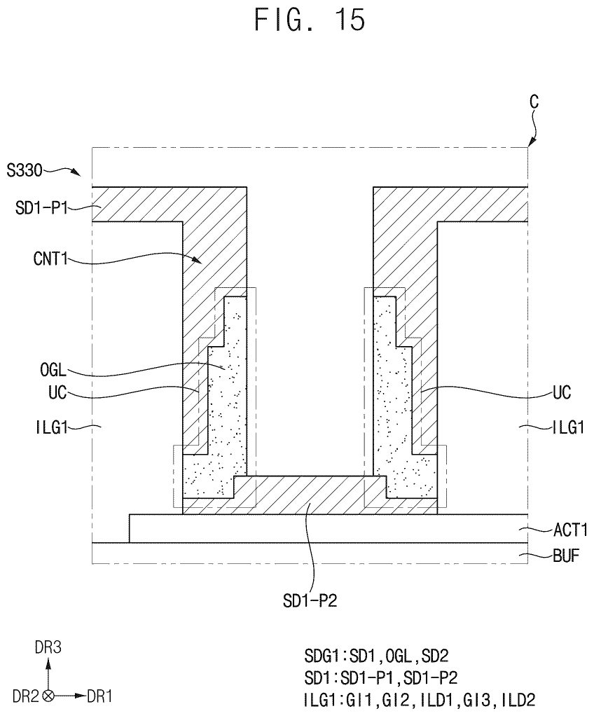

As illustrated in FIGS. 14 and 15, the organic layer pattern OGL may be formed by patterning the preliminary organic layer POGL (S330).

In an embodiment, the organic layer pattern OGL may be formed by exposing the preliminary organic layer POGL using the first conductive pattern SD1-P1 as a mask. In this case, the preliminary organic layer POGL may include a positive photosensitive organic material. That is, by using the first conductive pattern SD1-P1 as an exposure mask, the preliminary organic layer POGL may be patterned through exposure and development. Accordingly, the organic layer pattern OGL may be formed. The first conductive pattern SD1-P1 may block light UV provided from the outside. Accordingly, the light UV may overlap the first conductive pattern SD1-P1 in a plan view, and the light UV may not reach the preliminary organic layer POGL positioned under the first conductive pattern SD1-P1. In contrast, the light UV may reach the preliminary organic layer POGL positioned on the first conductive pattern SD1-P1. In addition, the light UV may reach the preliminary organic layer POGL spaced apart from the first conductive pattern SD1-P1 in a plan view.

When the preliminary organic layer POGL includes a positive photosensitive organic material, a portion where the light UV does not reach may remain in a cured state and may not be dissolved in the developer. In this case, using a predetermined developer, one portion of the preliminary organic layer POGL may be selectively removed depending on the change in chemical properties of a portion where the light UV reaches and a portion where the light UV does not reach. Accordingly, the preliminary organic layer POGL may be patterned by selectively removing the portion of the preliminary organic layer POGL where the light UV reaches. Accordingly, the organic layer pattern OGL may be formed.

In another embodiment, the organic layer pattern OGL may be formed by etching the preliminary organic layer POGL using the first conductive pattern SD1-P1 as a mask. In this case, the preliminary organic layer POGL may include a non-photosensitive organic material. That is, by using the first conductive pattern SD1-P1 as an etch mask, the preliminary organic layer POGL may be patterned through dry etching. That is, a portion of the preliminary organic layer POGL positioned on the first conductive pattern SD1-P1 and a portion of the preliminary organic layer POGL spaced apart from the first conductive pattern SD1-P1 in a plan view may be etched. In contrast, a portion of the preliminary organic layer POGL that overlaps the first conductive pattern SD1-P1 in a plan view and is disposed under the first conductive pattern SD1-P1 may not be etched. Accordingly, the organic layer pattern OGL may be formed.

The organic layer pattern OGL may be disposed in the first opening CNT1 and may contact the first conductive pattern SD1-P1 and the second conductive pattern SD1-P2. In an embodiment, the organic layer pattern OGL may fill a space defined by the undercut structure UC. As the organic layer pattern OGL fills the space defined by the undercut structure UC, the organic layer pattern OGL may cover a stepped structure of the side surface of the first conductive pattern SD1-P1. The organic layer pattern OGL may expose a portion of the second conductive pattern SD1-P2.

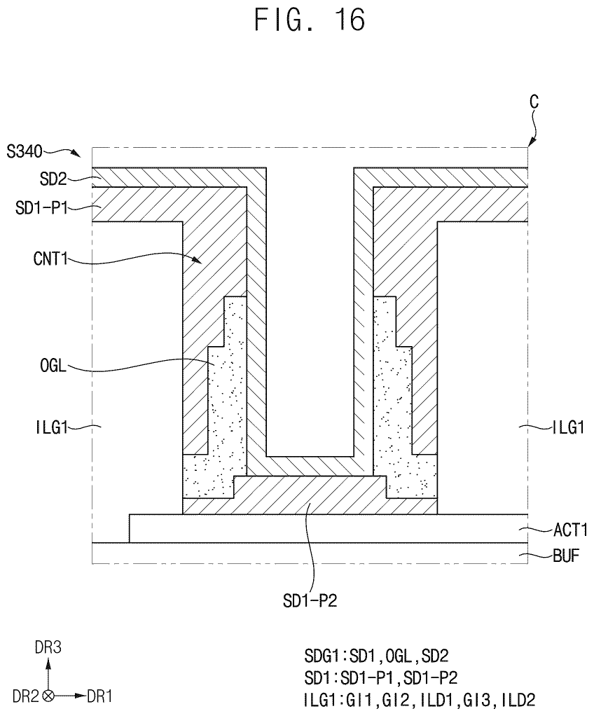

As illustrated in FIG. 16, the second conductive layer SD2 that covers the organic layer pattern OGL and the side surface of the first conductive pattern SD1-P1 and contacts the second conductive pattern SD1-P2 may be formed (S340). In an embodiment, the second conductive layer SD2 may be formed through a sputtering process.

The second conductive layer SD2 may cover the organic layer pattern OGL and the side surface of the first conductive pattern SD1-P1, and may contact the second conductive pattern SD1-P2. Specifically, the second conductive layer SD2 may cover the upper surface of the second conductive pattern SD1-P2 exposed from the organic layer pattern OGL.

In an embodiment, the second conductive layer SD2 may continuously extend in the first opening CNT1. That is, as the organic layer pattern OGL fills the space defined by the undercut structure UC, the second conductive layer SD2 may continuously extend in the first opening CNT1 without being disconnected. Accordingly, the second conductive layer SD2 may be electrically connected to a first source area of the first active pattern ACT1 through the second conductive patterns SD1-P2.

Accordingly, a first transistor TRI including the first active pattern ACT1, the first gate electrode GE1, the first source-drain structure SDG1, and the second source-drain structure SDG2 may be formed.

A source electrode SE and a drain electrode DE may be formed on the second inter-layer insulating layer ILD2. The source electrode SE may be connected to a second source area of the second active pattern ACT2 through the second opening CNT2. The drain electrode DE may be connected to a second drain area of the second active pattern ACT2 through the second opening CNT2.

In an embodiment, each of the source electrode SE and the drain electrode DE may be formed through the same process using the same material as the first conductive layer SD1. In this case, in the forming the first conductive layer SD1 (S310), a second transistor TR2 including the second active pattern ACT2, the third gate electrode GE3, the source electrode SE, and the drain electrode DE may be formed.

In another embodiment, each of the source electrode SE and the drain electrode DE may include a first layer formed using the same material as the first conductive layer SD1 and a second layer disposed on the first layer and formed using the same material as the second conductive layer SD2. In this case, in the forming the second conductive layer SD2 (S340), the second transistor TR2 including the second active pattern ACT2, the third gate electrode GE3, the source electrode SE, and the drain electrode DE may be formed.

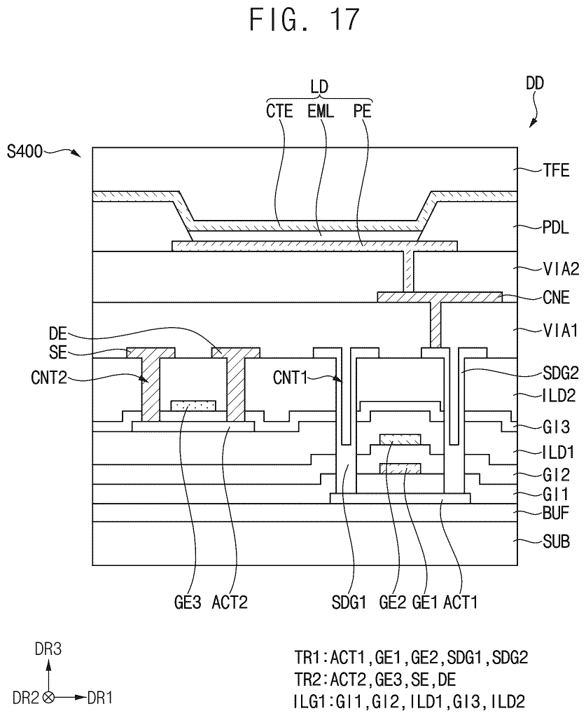

Referring to FIG. 17, a light emitting element LD may be formed on the first source-drain structure SDG1 and the second source-drain structure SDG2 (S400).

A first via-insulating layer VIA1 covering the source electrode SE, the drain electrode DE, the first source-drain structure SDG1, and the second source-drain structure SDG2 may be formed on the second inter-layer insulating layer ILD2. A connection electrode CNE may be formed on the first via-insulating layer VIA1.

A second via-insulating layer VIA2 covering the connection electrode CNE may be formed on the first via-insulating layer VIA1, and a pixel electrode PE may be formed on the second via-insulating layer VIA2.

A pixel defining layer PDL may be formed on the second via-insulating layer VIA2, and a light emitting layer EML may be formed on the pixel electrode PE. A common electrode CTE may be formed on the pixel defining layer PDL and the light emitting layer EML. Accordingly, the light emitting element LD including the pixel electrode PE, the light emitting layer EML, and the common electrode CTE may be formed. An encapsulation layer TFE may be formed on the common electrode CTE.

The present disclosure may be applied to various display devices. For example, the present disclosure is applicable to various display devices such as display devices for vehicles, ships and aircraft, portable communication devices, display devices for exhibition or information transmission, medical display devices, and the like.

The foregoing is illustrative of the embodiments of the present disclosure, and is not to be construed as limiting thereof. Although a few embodiments have been described with reference to the figures, those skilled in the art will readily appreciate that many variations and modifications may be made therein without departing from the spirit and scope of the present disclosure as defined in the appended claims.

What is claimed is:

1. A display device comprising:
a substrate;
an active pattern disposed on the substrate;
an insulating layer disposed on the active pattern and defining an opening exposing a portion of the active pattern;
a first conductive layer including a first conductive pattern and a second conductive pattern, wherein the first conductive pattern is disposed on the insulating layer and contacts a side surface of the insulating layer defining the opening, and the second conductive pattern is disposed on the active pattern in the opening and is disconnected from the first conductive pattern;
an organic layer pattern disposed in the opening, contacting the first conductive pattern and the second conductive pattern, and exposing a portion of the second conductive pattern; and
a second conductive layer covering the organic layer pattern and a side surface of the first conductive pattern, and contacting the second conductive pattern.

2. The display device of claim 1, wherein an edge of an upper surface of the first conductive pattern protrudes further than an edge of a lower surface of the first conductive pattern in a direction toward a center of the opening, and
the first conductive pattern and the second conductive pattern define an undercut structure in the opening.

3. The display device of claim 2, wherein the organic layer pattern is disposed to fill a space defined by the undercut structure.

4. The display device of claim 1, wherein the organic layer pattern connects the first conductive pattern and the second conductive pattern, which are disconnected from each other.

5. The display device of claim 1, wherein the second conductive layer extends continuously in the opening.

6. The display device of claim 5, wherein the second conductive layer covers an upper surface of the second conductive pattern exposed from the organic layer pattern.

7. The display device of claim 1, wherein the organic layer pattern includes a positive photosensitive organic material.

8. The display device of claim 1, wherein the organic layer pattern includes a non-photosensitive organic material.

9. The display device of claim 1, wherein the active pattern includes a first active pattern disposed on the substrate and a second active pattern disposed on the first active pattern,
the opening includes a first opening exposing a portion of the first active pattern and a second opening exposing a portion of the second active pattern, and
the organic layer pattern is disposed in the first opening.

10. The display device of claim 9, wherein the organic layer pattern is further disposed in the second opening.

11. A method of manufacturing a display device, the method comprising:
forming an active pattern on a substrate and forming an insulating layer on the active pattern;
forming an opening exposing a portion of the active pattern in the insulating layer;
forming a first conductive layer including a first conductive pattern and a second conductive pattern, wherein the first conductive pattern is disposed on the insulating layer and contacts a side surface of the insulating layer defining the opening, and the second conductive pattern is disposed on the active pattern in the opening and is disconnected from the first conductive pattern;
forming a preliminary organic layer on the first conductive layer;
forming an organic layer pattern, which contacts the first conductive pattern and the second conductive pattern in the opening and exposes a portion of the second conductive pattern, by patterning the preliminary organic layer; and
forming a second conductive layer, which covers the organic layer pattern and a side surface of the first conductive pattern and contacts the second conductive pattern.

12. The method of claim 11, wherein an edge of an upper surface of the first conductive pattern is formed to protrude further than an edge of a lower surface of the first conductive pattern in a direction toward a center of the opening, and
the first conductive pattern and the second conductive pattern define an undercut structure in the opening.

13. The method of claim 12, wherein the organic layer pattern is formed to fill a space defined by the undercut structure.

14. The method of claim 13, wherein the organic layer pattern is formed by exposing the preliminary organic layer to a light using the first conductive pattern as a mask.

15. The method of claim 13, wherein the organic layer pattern is formed by etching the preliminary organic layer using the first conductive pattern as a mask.

16. The method of claim 11, wherein each of the first conductive layer and the second conductive layer is formed through a sputtering process.

17. The method of claim 11, wherein the second conductive layer is formed to extend continuously in the opening.

18. The method of claim 17, wherein the second conductive layer is formed to cover an upper surface of the second conductive pattern exposed from the organic layer pattern.

19. The method of claim 11, wherein the forming of the active pattern on the substrate includes forming a first active pattern on the substrate and forming a second active pattern on the first active pattern,
the forming of the opening in the insulating layer includes forming a first opening exposing a portion of the first active pattern and forming a second opening exposing a portion of the second active pattern, and
the organic layer pattern is formed in the first opening.

20. The method of claim 19, wherein the organic layer pattern is further formed in the second opening.
